(19) United States
(12) Patent Application Publication
(10) Pub. No.: US 2014/0182515 A1
(43) Pub. Date: Jul. 3, 2014

(54) SUBSTRATE PROCESSING APPARATUS, METHOD OF MANUFACTURING SEMICONDUCTOR DEVICE AND VAPORIZATION SYSTEM

(71) Applicant: HITACHI KOKUSAI ELECTRIC INC., Tokyo (JP)

(72) Inventors: Hirohisa YAMAZAKI, Toyama-shi (JP); Yuji TAKEBAYASHI, Toyama-shi (JP)

(73) Assignee: HITACHI KOKUSAI ELECTRIC INC., Tokyo (JP)

(21) Appl. No.: 14/140,837

(22) Filed: Dec. 26, 2013

(30) Foreign Application Priority Data
Dec. 27, 2012 (JP) 2012-286055

(51) Int. Cl. H01L 21/02

(52) U.S. Cl. CPC H01L 21/02104
USPC 118/722; 118/726; 239/136

(57) ABSTRACT

A substrate processing apparatus includes: a processing chamber configured to accommodate a substrate; a vaporized gas supply system which includes a vaporizer to vaporize a liquid precursor into a vaporized gas and is configured to supply the vaporized gas into the processing chamber; and a control unit configured to control the vaporized gas supply system to supply a liquid precursor and a carrier gas into a vaporization chamber formed in the vaporizer such that a ratio of a partial pressure of the liquid precursor to a total pressure in the vaporization chamber is equal to or lower than 20%.

### CROSS-REFERENCE TO RELATED APPLICATION

This application is based upon and claims the benefit of priority from Japanese Patent Application No. 2012-286055, filed on Dec. 27, 2012, the entire contents of which are incorporated herein by reference.

### TECHNICAL FIELD

The present disclosure relates to a substrate processing apparatus, a method of manufacturing a semiconductor device, and a vaporization system.

### BACKGROUND

As one process in a method of manufacturing a semiconductor device, there has been proposed a technique for using a liquid precursor to form a film on a substrate. When a liquid precursor is used to perform substrate processing such as forming a film, a precursor gas in a gaseous phase produced by vaporizing the liquid precursor is being used. A vaporizer is suitable to be used to vaporize a liquid precursor.

With miniaturization of semiconductor devices, a wafer surface area is increased and processing such as forming a film in a deeper groove is required. Accordingly, there is a need to increase a supply amount of a liquid precursor.

### SUMMARY

The present disclosure provides some embodiments of a substrate processing apparatus which is capable of increasing a supply amount of a liquid precursor, a method of manufacturing a semiconductor device, and a vaporization system.

According to one embodiment of the present disclosure, a substrate processing apparatus includes:

a processing chamber configured to accommodate a substrate;

a vaporized gas supply system which includes a vaporizer to vaporize a liquid precursor into a vaporized gas and is configured to supply the vaporized gas into the processing chamber; and

a control unit configured to control the vaporized gas supply system to supply the liquid precursor and a carrier gas into a vaporization chamber formed in the vaporizer such that a ratio of a partial pressure of the liquid precursor to a total pressure in the vaporization chamber is equal to or lower than 20%.

According to another embodiment of the present disclosure, a method of manufacturing a semiconductor device, includes:

vaporizing a liquid precursor into a vaporized gas by supplying the liquid precursor and a carrier gas into a vaporization chamber of a vaporizer such that a ratio of a partial pressure of the liquid precursor to a total pressure in the vaporization chamber is equal to or lower than 20%; and

supplying the vaporized gas into a processing chamber where a substrate is accommodated, and processing the substrate.

According to another embodiment of the present disclosure, a vaporization system includes:

a vaporizer configured to supply a liquid precursor and a carrier gas into a vaporization chamber of a vaporizer such that a ratio of a partial pressure of the liquid precursor to a total pressure in the vaporization chamber is equal to or lower than 20%, and vaporize the liquid precursor into a vaporized gas;

a gas filter; and

a mist filter.

### BRIEF DESCRIPTION OF THE DRAWINGS

FIG. 1 is a schematic longitudinal sectional view illustrating a substrate processing apparatus according to an embodiment of the present disclosure.

FIG. 2 is a schematic cross sectional view taken along line A-A in FIG. 1.

FIG. 3 is a schematic view illustrating a precursor supply system of the substrate processing apparatus according to an embodiment of the present disclosure.

FIG. 4 is a schematic longitudinal sectional view illustrating a vaporizer of the substrate processing apparatus according to an embodiment of the present disclosure.

FIG. 5 is a schematic perspective view illustrating a mist filter of the substrate processing apparatus according to an embodiment of the present disclosure.

FIG. 6 is a schematic exploded perspective view illustrating the mist filter of the substrate processing apparatus according to an embodiment of the present disclosure.

FIG. 7 is a schematic view illustrating a controller of the substrate processing apparatus according to an embodiment of the present disclosure.

FIG. 8 is a flow chart illustrating a process of manufacturing a zirconium oxide film using the substrate processing apparatus according to an embodiment of the present disclosure.

FIG. 9 is a timing chart illustrating the process of manufacturing the zirconium oxide film using the substrate processing apparatus according to an embodiment of the present disclosure.

FIGS. 10A and 10B are graphs showing a relationship between a flow rate of a liquid precursor supplied to the vaporizer and a pressure at an outlet of the vaporizer.

FIG. 11 is a bar graph showing a relationship between a total pressure and a partial pressure at the outlet of the vaporizer depending on vaporization conditions.

### DETAILED DESCRIPTION

In order to increase a supply amount of a liquid precursor, it is conceivable to lengthen the time for supplying the liquid precursor. However, lengthening the liquid precursor supply time may lead to an increase in time for substrate processing such as forming a film. In order to shorten the time for substrate processing such as forming a film, it is preferable in some embodiments to increase a vaporization amount of the liquid precursor each time to form a film in a short time.

However, under conventional conditions (for example, a flow rate of a dilution N₂ gas is 25 slm, a flow rate of a N₂ carrier gas is 1 slm, and a flow rate of a liquid precursor is 0.3 g/min, which will be described in more detail later), even when the liquid precursor is more supplied by increasing the flow rate of the liquid precursor, the liquid precursor cannot be sufficiently vaporized resulting in poor vaporization of the liquid precursor in a vaporization chamber. Therefore, pyrolysates and polymers of the liquid precursor may be deposited within the vaporizer, and problems such as an increase in foreign matter, blockages and the like may occur.

As an alternative method for increasing a vaporization amount of the liquid precursor, it may be contemplated that a flow rate of a dilution N₂ gas is reduced to lower the internal pressure of the vaporizer. However, in an apparatus for processing a plurality of substrates at once, such as a vertical batch type film forming apparatus, for the purpose of securing substrate processing uniformity such as film thickness uniformity, a flow rate of a N₂ gas in a supply tube cannot be reduced, which may result in difficulty in providing more vaporization amount.

In consideration of the above, in some embodiments of the present disclosure, it is possible to suppress or prevent clogging and foreign matter generated by deposits due to poor vaporization in the vaporizer.

Some embodiments of the present disclosure will now be described in more detail with reference to the accompanying drawings.

First, a substrate processing apparatus adapted to be used in an embodiment of the present disclosure will be described. The substrate processing apparatus is provided as one example of a semiconductor manufacturing apparatus used in manufacture of semiconductor devices.

In the following description, the substrate processing apparatus will be illustrated as a vertical batch type substrate processing apparatus for performing a film formation process and the like on a plurality of substrates at a time. However, it is noted that the present disclosure is not limited to such a vertical batch type substrate processing apparatus but may be, for example, applied to a single wafer type substrate processing apparatus for performing a film formation process on one substrate at a time.

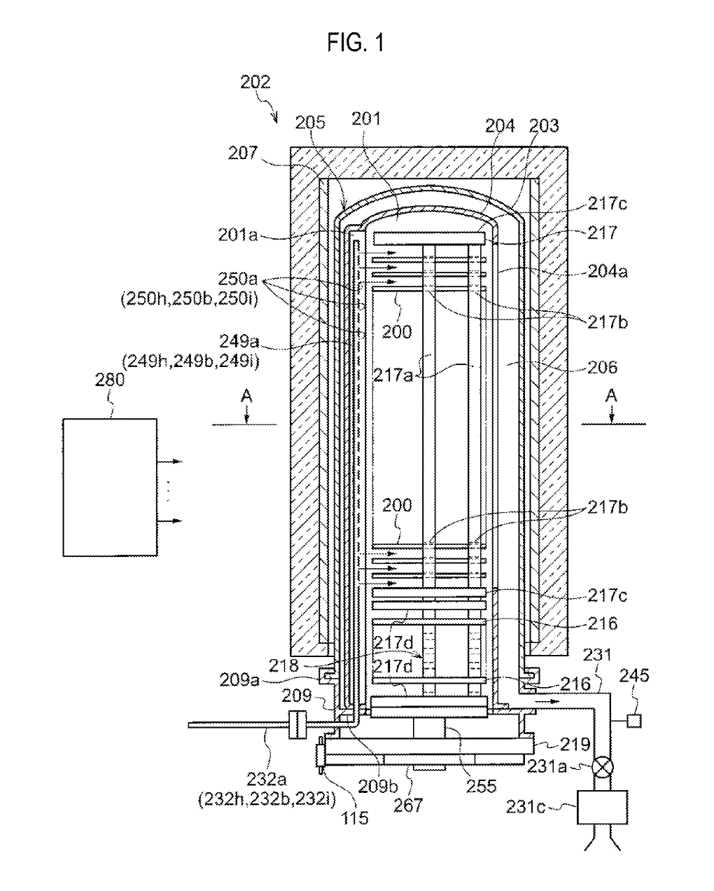

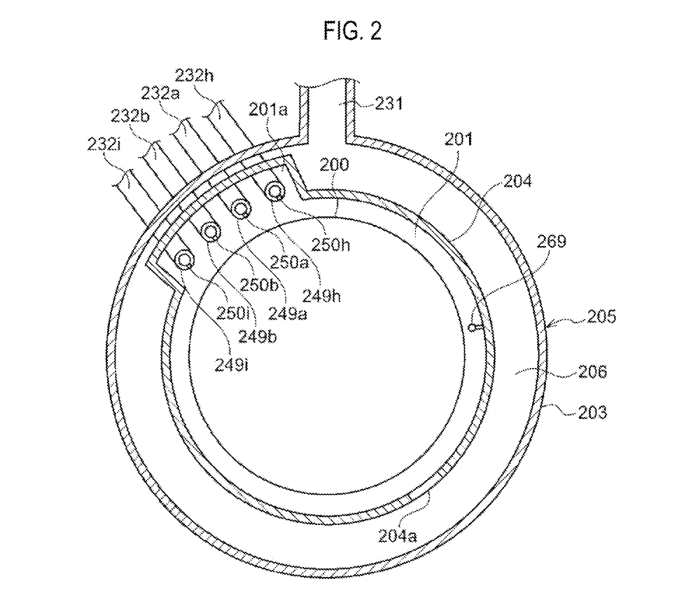

A processing furnace 202 of the substrate processing apparatus will be described below with reference to FIGS. 1 and 2.

### (Processing Furnace)

The processing furnace 202 includes a vertical process tube 205 serving as a reaction tube, which is vertically disposed to provide its perpendicular center line and is fixedly supported by a housing (not shown). The process tube 205 includes an inner tube 204 and an outer tube 203. Each of the inner tube 204 and the outer tube 203 is made of a heat-resistant material such as quartz (SiO₂), silicon carbide (SiC) or the like and is integrally formed in a cylindrical shape.

The inner tube 204 is formed in a cylindrical shape with its top blocked and its bottom opened. Within the inner tube 204, a processing chamber 201 is formed to accommodate and process wafers 200. In the processing chamber 201, the wafers 200 are stacked in multiple stages in horizontal positions by a boat 217 serving as a substrate holder. The bottom opening of the inner tube 204 constitutes a furnace opening through which the boat 217 holding the wafers 200 is inserted/removed. Accordingly, the inner diameter of the inner tube 204 is set to be larger than the maximum outer diameter of the boat 217 holding the wafers 200. The outer tube 203 has a shape similar to that of the inner tube 204 and its inner diameter is larger than that of the inner tube 204. The outer tube 203 is formed in a cylindrical shape with its top blocked and its bottom opened and covers the inner tube 204 in concentricity in such a manner to surround the outside of the inner tube 204. A lower end portion of the outer tube 203 is attached to a flange 209a above a manifold 209 via an O-ring (not shown) and is air-tightly sealed by the O-ring. A lower end portion of the inner tube 204 is mounted on a circular ring portion 209b in the inside of the manifold 209. The manifold 209 is removably attached to the inner tube 204 and the outer tube 203 to facilitate cleaning and maintenance for the inner tube 204 and the outer tube 203. As the manifold 209 is supported by the housing (not shown), the process tube 205 remains in an erect state.

### (Exhaust Unit)

An exhaust pipe 231 for exhausting the inner atmosphere of the processing chamber 201 is connected to a portion of a side wall of the manifold 209. An exhaust port for exhausting the inner atmosphere of the processing chamber 201 is formed at a connection between the manifold 209 and the exhaust pipe 231. The exhaust pipe 231 communicates with an exhaust passage, which is defined by a gap formed between the inner tube 204 and the outer tube 203, via the exhaust port. The exhaust passage has a cross section in a circular ring shape having a certain width. On a path of the exhaust pipe 231 are disposed a pressure sensor 245, an APC (Auto Pressure Controller) valve 231a serving as a pressure regulation valve, and a vacuum pump 231c serving as a vacuum exhaust device in this order from the upstream. The vacuum pump 231c is configured to vacuum-exhaust so that the internal pressure of the processing chamber 201 can be set to a predetermined pressure (predetermined degree of vacuum). A controller 280 is electrically connected to the APC valve 231a and the pressure sensor 245. The controller 280 is configured to control a degree of opening of the APC valve 231a based on a pressure detected by the pressure sensor 245 so that the internal pressure of the processing chamber 201 reaches an intended pressure at an intended timing. An exhaust unit (exhaust system) is mainly constituted by the exhaust pipe 231, the pressure sensor 245 and the APC valve 231a. The vacuum pump 231c may also be included in the exhaust unit.

### (Substrate Holder)

A seal cap 219 for blocking the bottom opening of the manifold 209 is in contact with the manifold 209 from the vertical lower side. The seal cap 219 is formed in a disc shape having an outer diameter equal to or greater than the outer diameter of the outer tube 203 and is vertically raised and lowered in a vertical position by a boat elevator 115 which is installed perpendicularly to the outside of the process tube 205.

The boat 217 serving as a substrate holder holding the wafers 200 is vertically erected on and supported by the seal cap 219. The boat 217 includes a pair of upper and lower end plates 217c and a plurality of holding members 217a arranged vertically between the end plates 217c. The end plates 217c and the holding members 217a are made of a heat-resistant material such as quartz (SiO₂), silicon carbide (SiC) or the like. Each of the holding members 217a has a number of holding grooves 217b formed therein at regular intervals in the longitudinal direction. When circumferential edges of the wafers 200 are respectively inserted in the holding grooves 217b of the same stage in the plurality of holding members 217a, the plurality of wafers 200 are stacked and held in multiple stages, with their centers aligned in the horizontal position.

In addition, a pair of upper and lower auxiliary end plates 217d is disposed between the boat 217 and the seal cap 219 and is supported by a plurality of auxiliary holding members 218. Each of the auxiliary holding members 218 has a number of holding grooves formed therein. A plurality of disc-shaped heat insulating plates 216 made of a heat-resistant material such as quartz (SiO₂), silicon carbide (SiC) or the like are loaded in the holding grooves in multiple stages in the horizontal position. The heat insulating plates 216 prevent heat from being transferred from a heater unit 207 to the manifold 209 side.

A rotation mechanism for rotating the boat 217 is provided on the opposite side of the seal cap 219 to the processing chamber 201. A shaft 255 of the rotation mechanism 267 passes through the seal cap 219 and supports the boat 217 from below. When the shaft 255 is rotated, the wafers 200 can be rotated within the processing chamber 201. The seal cap 219 is configured to be vertically raised and lowered by the above-mentioned boat elevator 115, thereby allowing the boat 217 to be transferred in/out of the processing chamber 201.

### (Heater Unit)

The heater unit 207 serving as a heating mechanism for heating the process tube 205 uniformly or to a predetermined distribution of temperature is installed in the outside of the outer tube 203 in such a manner to surround the outer tube 203. The heater unit 207 remains vertically installed by being supported by the housing (not shown) of the substrate processing apparatus and is configured as a resistance heater such as a carbon heater or the like. A temperature sensor 269 serving as a temperature detector is installed in the process tube 205. A heating unit (heating system) of this embodiment is mainly constituted by the heater unit 207 and the temperature sensor 269.

### (Gas Supply Unit)

In a side wall of the inner tube 204 (a position in the 180 degree opposite side to an exhaust hole 204a to be described later) is formed a channel-shaped vertically-elongated preliminary chamber 201a projecting outwardly from the side wall of the inner tube 204 in the radial direction of the inner tube 204. A side wall of the preliminary chamber 201a constitutes a part of the side wall of the inner tube 204. In addition, an inner wall of the preliminary chamber 201a forms a part of an inner wall of the processing chamber 201. Within the preliminary chamber 201a are installed nozzles 249i, 2449b, 249a and 249h for supplying gas into the processing chamber 201, which extend in the stacking direction of the wafers 200 from a lower part to an upper part of the inner wall of the preliminary chamber 201a along the inner wall of the preliminary chamber 201a (i.e., the inner wall of the processing chamber 201). That is, the nozzles 249i, 2449b, 249a and 249h are installed in a region horizontally surrounding a lateral side of a wafer arrangement region along the wafer arrangement region. The nozzles 249i, 2449b, 249a and 249h are configured as L-like elongated nozzles, with their horizontal portions formed to pass through the manifold 209 and their vertical portions formed to rise at least from one end side of the wafer arrangement region toward the other end side thereof. Although FIG. 1 shows one nozzle for convenience, in actuality, the four nozzles 249i, 2449b, 249a and 249h are installed as shown in FIG. 2. A number of gas supply holes 250i, 250b, 250a and 250h for supplying gas (precursor gas) are formed in sides of the nozzle 249i, 2449b, 249a and 249h, respectively. The gas supply holes 250i, 250b, 250a and 250h have the same or different opening areas over the top from the bottom and are formed at the same pitches.

End portions of the horizontal portions of the nozzle 249i, 2449b, 249a and 249h passing through the manifold 209 are respectively connected to gas supply pipes 232i, 232b, 232a and 232h serving as gas supply lines in the outside of the process tube 205.

In this manner, a gas supplying method is to transfer gas via the nozzle 249i, 2449b, 249a and 249h arranged in the preliminary chamber 201a and then eject the gas into the inner tube 204 in the vicinity of the wafers 200 from the gas supply holes 250i, 250b, 250a and 250h respectively opened in the nozzle 249i, 2449b, 249a and 249h.

The exhaust hole 204a, which is for example a slit-like through hole, is formed to be vertically elongated in a position on the side wall of the inner tube 204, which faces the nozzle 249i, 2449b, 249a and 249h, that is, a position on the opposite side to the preliminary chamber 201a, is formed to be vertically elongated. The processing chamber 201 communicates with an exhaust passage 206, which is defined by a gap formed between the inner tube 204 and the outer tube 203, via the exhaust hole 204a. Accordingly, gas supplied from the gas supply holes 250i, 250b, 250a and 250h into the processing chamber 201 flows into the exhaust passage 206 via the exhaust hole 204a, flows into the exhaust pipe 231 via the exhaust port, and is then discharged out of the processing furnace 202. Gas supplied from the gas supply holes 250i, 250b, 250a and 250h into the vicinity of the wafers 200 in the processing chamber 201 flows in a horizontal direction, i.e., a direction in parallel to the surfaces of the wafers 200 and then flows into the exhaust passage 206 via the exhaust hole 204a. That is, the main flow of gas in the processing chamber 201 is in the horizontal direction, i.e., parallel to the surfaces of the wafers 200. The exhaust hole 204a is not limited to being configured as a slit-like through hole but may be configured as a plurality of holes.

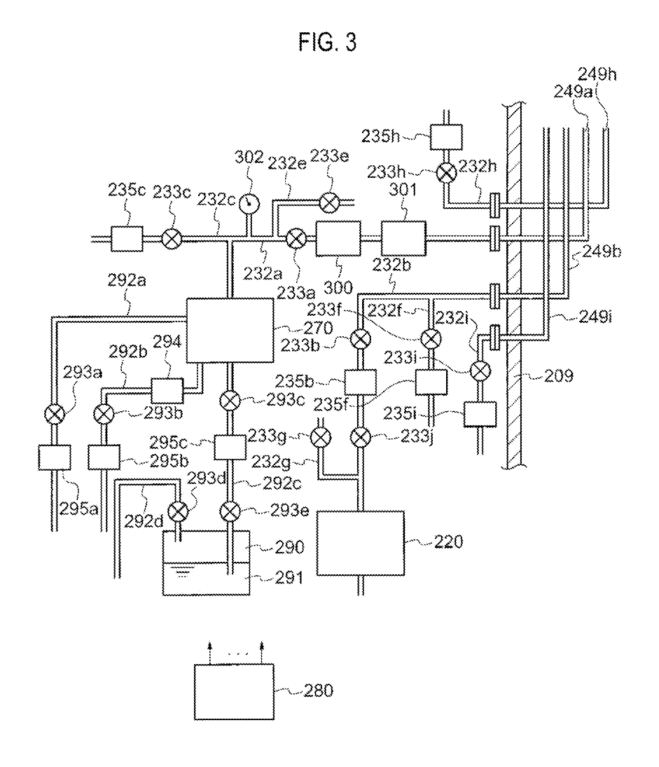

Referring to FIG. 3, the gas supply pipe 232i is provided with a MFC (Mass Flow Controller) 235i serving as a flow rate controller (flow rate control unit) and a valve 233i serving as an opening/closing valve in this order from the upstream. An inert gas such as a N₂ gas is supplied into the processing chamber 201 via the gas supply pipe 232i and the nozzle 249i. A first inert gas supply system is mainly constituted by the nozzle 249i, the gas supply pipe 232i, the MFC 235i and the valve 233i.

The gas supply pipe 232h is provided with a MFC (Mass Flow Controller) 235h serving as a flow rate controller (flow rate control unit) and a valve 233h serving as an opening/closing valve in this order from the upstream. An inert gas such as a N₂ gas is supplied into the processing chamber 201 via the gas supply pipe 232h and the nozzle 249h. A second inert gas supply system is mainly constituted by the nozzle 249h, the gas supply pipe 232h, the MFC 235h and the valve 233h.

The gas supply pipe 232b is provided with an ozonizer 220 for generating an ozone (O₃) gas, a valve 233j serving as an opening/closing valve, a MFC (Mass Flow Controller) 235b serving as a flow rate controller (flow rate control unit) and a valve 233b serving as an opening/closing valve in this order from the upstream. The above-mentioned nozzle 249b is connected to a leading end of the gas supply pipe 232b.

The upstream side of the gas supply pipe 232b is connected to an oxygen gas source (not shown) for supplying an oxygen (O₂) gas. The O₂ gas supplied into the ozonizer 220 is changed into an O₃ gas by the ozonizer 220, which is then supplied into the processing chamber 201.

A vent line 232g connected to the exhaust pipe 231 is connected to the gas supply pipe 232b between the ozonizer 220 and the valve 232j. The vent line 232g is provided with a valve 233g serving as an opening/closing valve. If no O₃ gas is supplied into the processing chamber 201, a precursor gas is supplied into the vent line 232g via the valve 233g. When the valve 233g is closed and the valve 233g is opened, the supply of the O₃ gas into the processing chamber 201 can be stopped while continuing the generation of the O₃ gas by the ozonizer 220. Although it takes a predetermined time to refine the O₃ gas stably, it is possible to switch between the supply and stop of the O₃ gas into the processing chamber 201 in a very short time by switching between the valve 233j and the valve 233g.

In addition, an inert gas supply pipe 232f is connected to the gas supply pipe 232b at the downstream side of the valve 233b. The inert gas supply pipe 232f is provided with a MFC (Mass Flow Controller) 235f serving as a flow rate controller (flow rate control unit) and a valve 233f serving as an opening/closing valve in this order from the upstream.

A first gas supply system is mainly constituted by the vent line 232g, the ozonizer 220, the valves 233j, 233g and 233b, the MFC 235b, the nozzle 249, the inert gas supply pipe 232f, the MFC 235f and the valve 233f.

The gas supply pipe 232a is provided with a vaporizer 270 serving as a vaporization device (vaporization unit) for generating a vaporized gas serving as a precursor gas by vaporizing a liquid precursor, a valve 233a serving as an opening/closing valve, a mist filter 300 and a gas filter 301 in this order from the upstream. The above-mentioned nozzle 249a is connected to a leading end of the gas supply pipe 232a. When the valve 233a is opened, the vaporized gas generated in the vaporizer 270 is supplied into the processing chamber 201 via the nozzle 249a.

An inert gas supply pipe 232c is connected to the gas supply pipe 232a between the vaporizer 270 and the valve 233a. The inert gas supply pipe 232c is provided with a MFC (Mass Flow Controller) 235c serving as a flow rate controller (flow rate control unit) and a valve 233c serving as an opening/closing valve in this order from the upstream. An inert gas such as a N₂ gas is supplied from the inert gas supply pipe 232c. The vaporized gas generated by the vaporizer 270 is diluted by the inert gas from the inert gas supply pipe 232c and is then supplied into the processing chamber 201. When the vaporized gas generated by the vaporizer 270 is diluted by the inert gas from the inert gas supply pipe 232c, it is possible to adjust processing uniformity of the wafers 200, such as film thickness uniformity among the wafers 200 mounted on the boat 217.

A vent line 232e connected to the exhaust pipe 231 is connected to the gas supply pipe 232a between the vaporizer 270 and the valve 233a. The vent line 232e is provided with a valve 233e serving as an opening/closing valve. If the vaporized gas generated by the vaporizer 270 is not supplied into the processing chamber 201, the vaporized gas is supplied into the vent line 232e via the valve 233e. When the valve 233a is closed and the valve 233e is opened, the supply of vaporized gas into the processing chamber 201 can be stopped while continuing the generation of the vaporized gas by the ozonizer 220. Although it takes a predetermined time to generate the vaporized gas stably, it is possible to switch between the supply and stop of the vaporized gas into the processing chamber 201 in a very short time by switching between the valve 233a and the valve 233e.

A pressure gauge 302 is connected to the gas supply pipe 232a between the vaporizer 270 and the valve 233a.

The upstream side of the vaporizer 270 is connected with a liquid precursor supply pipe 292c for supplying a liquid precursor into the vaporizer 270, an inert gas supply pipe 292a for supplying an inert gas into the upper portion of the vaporizer 270, and an inert gas supply pipe 292b for supplying an inert gas into the lower portion of the vaporizer 270. An inert gas such as a N₂ gas is supplied from the inert gas supply pipes 292a and 292b.

The liquid precursor supply pipe 292c is provided with a liquid precursor supply tank 290 for storing a liquid precursor, a valve 293e serving as an opening/closing valve, a LMFC (Liquid Mass Flow Controller) 295c serving as a liquid flow rate controller (liquid flow rate control unit) for controlling a flow rate of liquid precursor, and a valve 293c serving as an opening/closing valve in this order from the upstream. An upstream end of the liquid precursor supply pipe 292c is immersed in a liquid precursor 291 within the liquid precursor supply tank 290. The upper portion of the liquid precursor supply tank 290 is connected with a pressure-feed gas supply pipe 292d for supplying an inert gas such as a N₂ gas or the like. The upstream side of the pressure-feed gas supply pipe 292d is connected to a pressure-feed gas supply source (not shown) for supplying an inert gas such as a N₂ gas or the like as a pressure-feed gas. The pressure-feed gas supply pipe 292d is provided with a valve 293d serving as an opening/closing valve. When the opening/closing valve 293d is opened, the pressure-feed gas is supplied into the liquid precursor supply tank 290. When the opening/closing valve 293e and the opening/closing valve 293c are opened, the liquid precursor 291 in the liquid precursor supply tank 290 is pressure-fed (supplied) into the vaporizer 270. A flow rate of the liquid precursor 291 supplied into the vaporizer 270 (i.e., a flow rate of vaporized gas generated in the vaporizer 270 and supplied into the processing chamber 201) is controlled by the LMFC 295c.

The inert gas supply pipe 292a is provided with a MFC (Mass Flow Controller) 295a servings as a flow controller (flow rate control unit) and a valve 293a serving as an opening/closing valve in this order from the upstream. An inert gas such as a N₂ gas is supplied into the upper portion of the vaporizer 270.

The inert gas supply pipe 292b is provided with a MFC (Mass Flow Controller) 295b servings as a flow controller (flow rate control unit), a valve 293b serving as an opening/closing valve, and a heat exchanger 294 in this order from the upstream. An inert gas such as a N₂ gas is supplied into the lower portion of the vaporizer 270.

A second gas supply system is mainly constituted by the liquid precursor supply pipe 292c, the valve 293e, the LMFC 295c, the valve 293c, the inert gas supply pipe 292a, the MFC 295a, the valve 293a, the inert gas supply pipe 292b, the MFC 295b, the valve 293b, the heat exchanger 294, the vaporizer 270, the gas supply pipe 232a, the inert gas supply pipe 232c, the MFC 235c, the valve 233c, the pressure gauge 302, the vent line 232e, the valve 233e, the valve 233a, the mist filter 300, the gas filter 301 and the nozzle 249a. The pressure-feed gas supply pipe 292d, the valve 293d and the liquid precursor supply tank 290 may be also included in the second gas supply system.

For example, a zirconium precursor gas as a precursor gas, which is a metal-containing gas, i.e., a gas containing zirconium (Zr) (zirconium-containing gas), is supplied from the gas supply pipe 232a into the processing chamber 201 via the LMFC 295c, the vaporizer 270, the mist filter 300, the gas filter 301, the nozzle 249a and so on. An example of a zirconium-containing gas may include tetrakisethylmethylamino zirconium (Zr[N(CH₃)C₂H₅]₄), abbreviation: TEMAZ). The TEMAZ is a liquid at the room temperature and atmospheric pressure. The liquid TEMAZ is stored as the liquid precursor in the liquid precursor supply tank 290.

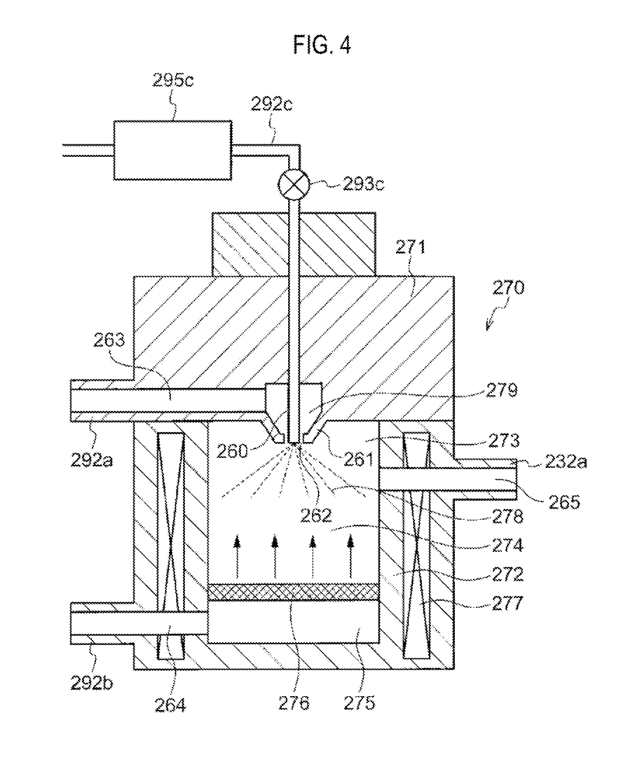

Referring to FIG. 4, the vaporizer 270 includes an upper housing 271 and a lower housing 272. A vaporizing chamber 274 is formed within the lower housing 272. A filter 276 is disposed within the vaporizing chamber 274. The vaporizing chamber 274 is separated into an upper vaporizing chamber 273 and a lower vaporizing chamber 275 by the filter 276. The filter 276 is made of a sintered metal powder material. The inert gas supply pipe 292b is connected to the lower vaporizing chamber 275 via a gas inlet pipe 264. The gas supply pipe 232a is connected to the upper vaporizing chamber 273 via a vaporized gas outlet pipe 265. A heater 277 is buried in the lower housing 272. A gas inlet space 279 is formed in the lower central portion of the upper housing 271. The inert gas supply pipe 292a is connected to the gas inlet space 279 via a gas inlet pipe 263. A liquid precursor inlet pipe 260 is disposed to pass through the central portion of the upper hosing 271. The upstream side of the liquid precursor inlet pipe 260 is connected to the liquid precursor supply pipe 292c. A projection 261 is formed in the lower central portion of the upper housing 271. The projection 261 forms the lower portion of the gas inlet space 279. A gap (slit) 262 is formed between the projection 261 and the lower end portion of the liquid precursor inlet pipe 260.

A liquid precursor introduced into the upper vaporizing chamber 273 by the liquid precursor inlet pipe 260 becomes a mist (misty droplets) 278 by the inert gas such as the N₂ gas or the like ejected through the gap 262. The inert gas such as the N₂ gas or the like heated by the heat exchanger 294 (see FIG. 3) is supplied into the lower vaporizing chamber 275 via the gas inlet pipe 264 and is introduced into the upper vaporizing chamber 273 via the filter 276. A liquid precursor which has reached the filter 276 while remaining in a liquid state without becoming misty and penetrated into the filter 276 becomes misty by the heated inert gas such as the N₂ gas or the like supplied into the lower vaporizing chamber 275. The mist 278 is moved upward within the upper vaporizing chamber 273 by the heated inert gas such as the N₂ gas or the like supplied into the lower vaporizing chamber 275. While being moved, the mist 278 is vaporized by the radiant heat emitted from an inner wall of the lower housing 272 heated by the heater 277. The vaporized liquid precursor becomes a vaporized gas serving as a precursor gas, which is guided to the gas supply pipe 232a via the vaporized gas outlet pipe 265.

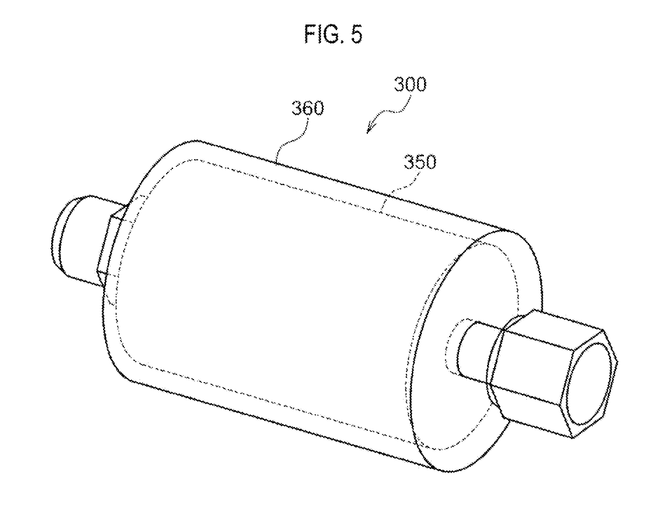

Referring to FIG. 5, the mist filter 300 includes a mist filter body 350 and a heater 360 which covers the mist filter body 350 and is located outside of the mist filter body 350.

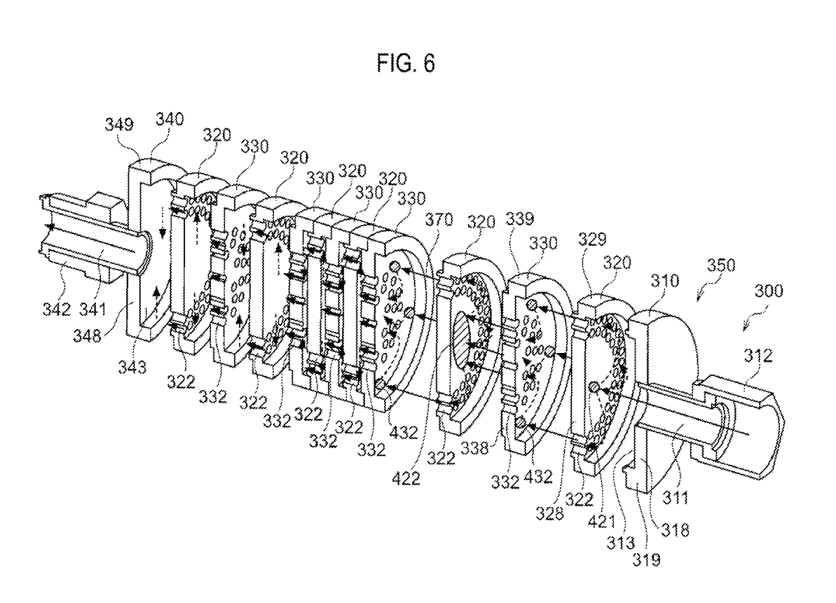

Referring to FIGS. 5 and 6, the mist filter body 350 of the mist filter 300 includes end plates 310 and 340 at both ends, and two types of plates 320 and 330 interposed between the end plates 310 and 340. A joint 312 is attached to the end plate 310. A joint 342 is attached to the end plate 340. A gas path 311 is formed in the end plate 310 and the joint 312. A gas path 341 is formed in the end plate 340 and the joint 342.

Each of the two types of plates 320 and 330 includes a plurality of plates which are alternately arranged between the end plates 310 and 340. Each plate 320 includes a flat plate 328 and a peripheral portion 329 formed on the periphery of the plate 328. Holes 322 are formed only in the vicinity of the periphery of the plate 328. Each plate 330 includes a flat plate 338 and a peripheral portion 339 formed on the periphery of the plate 338. Holes 332 are formed only in the vicinity of the center of the plate 338. The alternate arrangement of these plates 320 and 330 provides the complexity of entangled gas paths 370, which may result in an increased probability of collusion of droplets produced due to poor vaporization or condensation with heated walls (the plates 328 and 338). The size of the holes 322 and 332 depends on a pressure and is, for example, 1 to 3 mm in diameter.

The precursor gas in a gaseous phase produced when the liquid precursor 291 is vaporized by the vaporizer 270 (see FIG. 3) and the droplets produced due to poor vaporization or condensation are introduced from the gas path 311 formed in the end plate 310 and the joint 342 into the mist filter body 350 and then collide with a central portion 421 of the flat plate 328 of the first plate 320, thereafter, pass through the holes 322 formed in the vicinity of the periphery of the plate 328 and collide with a peripheral portion 432 of the flat plate 338 of the second plate 330, thereafter, pass through the holes 332 formed in the vicinity of the center of the plate 338 and collide with a central portion 422 of the flat plate 328 of the third plate 320, and thereafter, similarly, pass through the plates 330 and 320 sequentially, are introduced from the mist filter body 350 via the gas path 341 formed in the end plate 340 and the joint 342, and then are sent to the gas filter 301 (see FIG. 3) in the downstream.

The mist filter body 350 is heated from its outside by the heater 360 (see FIG. 5). As described above, the mist filter body 350 includes the plurality of plates 320, each of which includes the flat plate 328 and the peripheral portion 329 formed in the periphery of the plate 328, and the plurality of plates 330, each of which includes the flat plate 338 and the peripheral portion 339 formed in the periphery of the plate 338. Since the plate 328 and the peripheral portion 329 are integrally formed and the plate 338 and the peripheral portion 339 are integrally formed, when the mist filter body 350 is heated from its outside by the heater 360, heat is transferred to the flat plates 328 and 338 with efficiency.

Since the entangled complex gas paths 370 are constituted by the plurality of plates 320 and 330 in the mist filter body 350 as described above, a pressure loss in the mist filter body 350 is not excessively increased, which may result in an increased probability of collusion of the precursor gas in the gaseous phase by vaporization and the droplets produced due to poor vaporization or condensation with the heated flat plates 328 and 338. Then, the droplets produced due to poor vaporization or condensation are vaporized by being heated again while colliding with the heated flat plates 328 and 338 in the mist filter body 350 having a sufficient amount of heat.

With the mist filter 300 installed in the gas supply pipe 232a between the vaporizer 270 and the gas filter 301, if the liquid precursor is less likely to be vaporized or a flow rate of vaporization is high, the droplets produced due to poor vaporization or condensation are vaporized by being heated again while colliding with the walls of the plates 320 and the walls of the plates 330 in the mist filter 300 having a sufficient amount of heat. Then, the gas filter 301 disposed just before the processing chamber 201 collects the droplets remaining in the vaporizer 270 and the mist filter 300. The mist filter 300 serves to assist in vaporization and allows a reaction gas having no droplets produced due to poor vaporization to be supplied into the processing chamber 201, thereby providing a substrate processing such as high quality film forming. In addition, the mist filter 300 serves to assist the gas filter 301 and can suppress clogging of the gas filter 301, which may facilitate the maintenance of the gas filter 301 or extend a filter replacement cycle of the gas filter 301.

### (Controller)

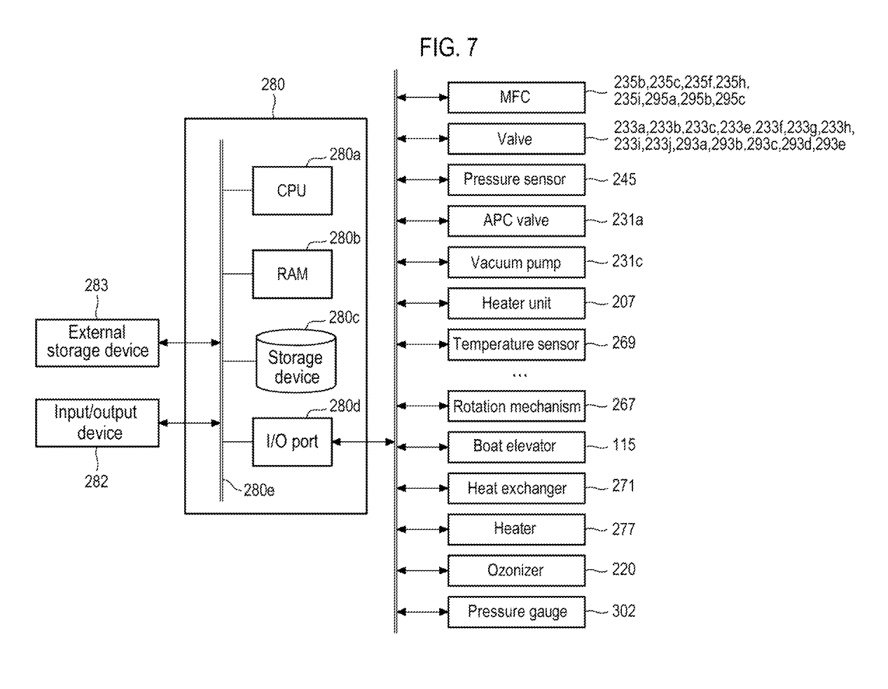

Referring to FIG. 7, the controller 280 as a control unit (control means) includes a computer having a CPU (Central Processing Unit) 280a, a RAM (Random Access Memory) 280b, a storage device 280c and an I/O port 280d. The RAM 280b, the storage device 280c and the I/O port 280d are configured to exchange data with the CPU 280a via an internal bus 280e. An input/output device 282 constituted by, for example, a touch panel or the like is connected to the controller 280.

The storage device 280c includes, for example, a flash memory, a HDD (Hard Disk Drive) or the like. Control programs to control an operation of the substrate processing apparatus and process recipes describing substrate processing procedures and conditions, which will be described later, are readably stored in the storage device 280c. The process recipes function as programs to cause the controller 280 to execute procedures in substrate processing, which will be described later, in order to achieve desired results. Hereinafter, these process recipes and control programs are collectively simply referred to as programs. As used herein, the term “programs” may be intended to include process recipes only, control programs only, or both. The RAM 280b is configured as a memory area (work area) in which programs and data read by the CPU 280a are temporarily stored.

The I/O port 280d is connected to the above-mentioned mass flow controllers 235b, 235c, 235f, 235h, 235i, 295a, 295b and 295c, valves 233a, 233b, 233c, 233e, 233f, 233g, 233h, 233i, 233j, 293a, 293b, 293c, 293d and 293e, pressure sensor 245, APC valve 231a, vacuum pump 231c, heater unit 207, temperature sensor 269, rotation mechanism 267, boat elevator 115, heat exchanger 294, heater 277, ozonizer 220, pressure gauge 302 and so on.

The CPU 280a reads and executes a control program from the storage device 280c and reads a process recipe from the storage device 280c according to an operation command input from the input/output device 282. In addition, the CPU 280a controls a flow rate adjustment operation of various gases by the mass flow controllers 235b, 235c, 235f, 235h, 235i, 295a, 295b and 295c and the valves 233a, 233b, 233c, 233e, 233f, 233g, 233h, 233i, 233j, 293a, 293b, 293c, 293d and 293e, a flow rate adjustment operation of liquid precursor by the liquid mass flow controller 295c, an opening/closing operation of the valves 233a, 233b, 233c, 233e, 233f, 233g, 233h, 233i, 233j, 293a, 293b, 293c, 293d and 293e, an opening/closing operation of the APC valve 231a, a pressure adjustment operation by the APC valve 231a based on the pressure sensor 245, a temperature adjustment operation of the heater unit 207 based on the temperature sensor 269, start and stop of the vacuum pump 231c, rotation and a rotation speed adjustment operation of the boat 217 by the rotation mechanism 267, an elevation operation of the boat 217 by the boat elevator 115, a temperature adjustment operation of the heat exchanger 294, a temperature adjustment operation of the heater 277, a pressure measurement operation by the pressure gauge 302, etc., according to contents of the read process recipe.

The controller 280 may be configured as a general-purpose computer without being limited to a dedicated computer. For example, in an embodiment, the controller 280 may be configured by preparing an external storage device (for example, a magnetic tape, a magnetic disk such as a flexible disk or a hard disk, an optical disk such as CD or DVD, a magneto-optical disk such as MO, and a semiconductor memory such as a USB memory or a memory card) 283 which stores the above-described programs and installing the programs from the external storage device 283 into the general-purpose computer. A means for providing the programs for the computer is not limited to the case where the programs are provided through the external storage device 283. For example, the programs may be provided using a communication means such as the Internet, a dedicated line or the like, without the external storage device 283. The storage device 280c and the external storage device 283 are implemented with a computer readable recording medium and will be hereinafter collectively simply referred to as a recording medium. The term “recording medium” may include the storage device 280c only, the external storage device 283 only, or both.

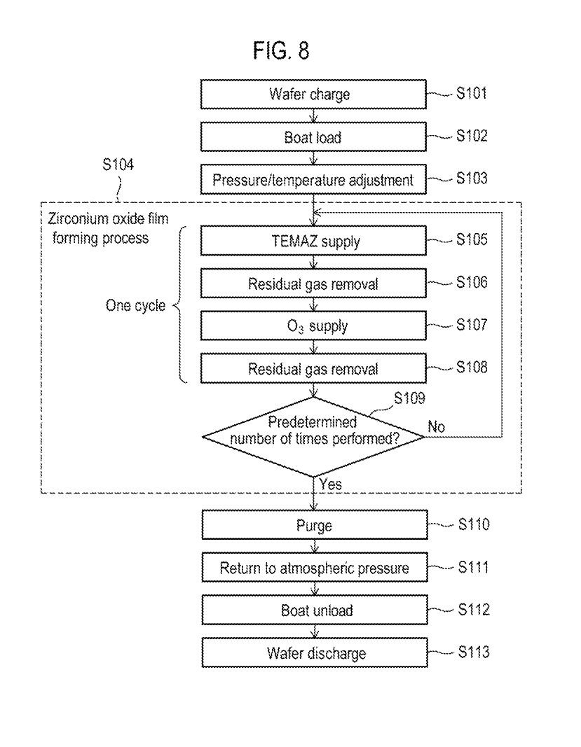

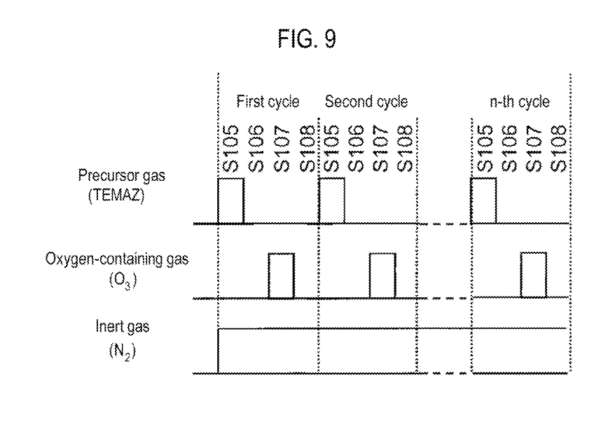

Subsequently, as one of the processes of manufacturing a semiconductor device using the vertical treatment furnace of the above-described substrate processing apparatus, an example of a sequence of forming an insulating film on a substrate will be now described with reference to FIGS. 8 and 9. In the following description, operations of various components constituting the substrate processing apparatus are controlled by the controller 280.

First, when a plurality of wafers 200 is loaded on the boat 217 (wafer charge) (see Step S101 in FIG. 8), the boat 217 supporting the plurality of wafers 200 is lifted and loaded into the processing chamber 201 by the boat elevator 115 (boat load) (see Step S102 in FIG. 8). In this state, the seal cap 219 seals the bottom of the manifold 209.

The interior of the processing chamber 201 is vacuum-exhausted by the vacuum pump 231c to set the interior to a desired pressure (degree of vacuum). At this time, the internal pressure of the processing chamber 201 is measured by the pressure sensor 245 and the APC valve 231a is feedback-controlled based on the measured pressure (pressure adjustment) (see Step S103 in FIG. 8). In addition, the interior of the processing chamber 201 is heated by the heater unit 207 to set the interior to a desired temperature. At this time, a state of electric conduction to the heater unit 207 is feedback-controlled based on the temperature information detected by the temperature sensor 269 such that the interior of the processing chamber 201 has a desired temperature distribution (temperature adjustment) (see Step S103 in FIG. 8). Subsequently, the wafers 200 are rotated as the boat 217 is rotated by the rotation mechanism 267.

Subsequently, an insulating forming process of forming a ZrO as an insulating film by supplying a TEMAZ gas and an O3 gas into the processing chamber 201 is performed (see Step S104 in FIG. 8). The insulating film forming process includes the following four steps which are sequentially performed.

### (Insulating Film Forming Process)

### <Step S105>

In Step S105 (see FIGS. 8 and 9, first process), the TEMAZ gas initially flows. The valve 233a of the gas supply pipe 232a is opened and the valve 233e of the vent line 232e is closed to allow the TEMAZ gas to flow into the gas supply pipe 232a via the mist filter 300 and the gas filter. A flow rate of the TEMAZ gas flowing into the gas supply pipe 232a is regulated by the liquid mass flow controller 295c. The TEMAZ gas with its flow rate regulated is supplied from the gas supply holes 250a of the nozzle 249a into the processing chamber 201 and is exhausted from the exhaust pipe 231. At the same time, the valve 233c is opened to allow the flow of an inert gas such as a N₂ gas or the like into the inert gas supply pipe 232c. A flow rate of the N₂ gas flowing into the inert gas supply pipe 232c is regulated by the mass flow controller 235c. The N₂ gas with its flow rate regulated is supplied into the processing chamber 201, along with the TEMAZ gas, and is exhausted from the exhaust pipe 231. The valve 233h is opened to allow the flow of an inert gas such as a N₂ gas or the like from the gas supply pipe 232h, the nozzle 249h and the gas supply holes 250h, and the valve 233i is opened to allow the flow of an inert gas such as a N₂ gas or the like from the gas supply pipe 232i, the nozzle 249i and the gas supply holes 250i.

At this time, the APC valve 231a is appropriately regulated to set the internal pressure of the processing chamber 201 to fall within a range of, for example, 50 to 400 Pa. The flow rate of TEMAZ gas controlled by the liquid mass flow controller 295c is set to fall within a range of, for example, 0.1 to 0.5 g/min. The time period during which the TEMAZ gas is exposed to the wafers 200, that is, gas supply time (irradiation time), is set to fall within a range of, for example, 30 to 240 seconds. At this time, the heater unit 207 is set to a temperature such that the temperature of the wafers 200 is set to fall within a range of, for example, 150 to 250 degrees C. A zirconium-containing layer is formed on each wafer 200 by the supply of TEMAZ gas.

### <Step S106>

In Step S106 (see FIGS. 8 and 9, second process), the valve 233a is closed and the valve 233e is opened to stop the supply of TEMAZ gas into the processing chamber 201 and to allow the flow of TEMAZ gas into the vent line 232e. At this time, with the APC valve 231a of the exhaust pipe 231 opened, the interior of the processing chamber 201 is vacuum-exhausted by the vacuum pump 231c to exclude an unreacted TEMAZ gas remaining in the processing chamber 201 or a TEMAZ gas remaining after contributing to the formation of the zirconium-containing layer.

At this time, the residual gas in the processing chamber 201 may not be completely excluded and the interior of the processing chamber 201 may not be completely purged. If an amount of the residual gas in the processing chamber 201 is very small, this has no adverse effect on the subsequent Step S107. In this case, there is no need to provide a high flow rate of the N₂ gas supplied into the processing chamber 201. For example, approximately the same volume of the N₂ gas as the processing chamber 201 may be supplied into the processing chamber 201 to purge the interior of the processing chamber 201 to such a degree that this has no adverse effect on Step S107. In this way, when the interior of the processing chamber 201 is not completely purged, purge time can be shortened, thereby improving throughput. This can also limit the consumption of the N₂ gas to the minimum required level for purging.

### <Step S107>

In Step S107 (see FIGS. 8 and 9, third process), after the residual gas in the processing chamber 201 is removed, when the valves 233j and 233b of the gas supply pipe 232b are opened and the valve 233g of the vent line 232g is closed, an O₃ gas generated by the ozonizer 220 is supplied from the gas supply holes 250b of the nozzle 249b into the processing chamber 201, with its flow rate regulated by the mass flow controller 235b, and is exhausted from the exhaust pipe 231. At the same time, the valve 233f is opened to allow the flow of N₂ gas into the inert gas supply pipe 232f. The N₂ gas is supplied into the processing chamber 201, along with the O₃ gas, and is exhausted from the exhaust pipe 231. In addition, the valve 233h is opened to allow the flow of an inert gas such a N₂ gas or the like from the gas supply pipe 232h, the nozzle 249h and the gas supply holes 250h, and the valve 233i is opened to allow the flow of an inert gas such a N₂ gas or the like from the gas supply pipe 232i, the nozzle 249i and the gas supply holes 250i.

When the O₃ gas is flowing, the APC valve 244 is appropriately regulated to set the internal pressure of the processing chamber 201 to fall within a range of, for example, 50 to 400 Pa. A flow rate of the O₃ gas controlled by the mass flow controller 235b is set to fall within a range of, for example, 10 to 20 slm. The time period during which the wafers 200 are exposed to the O₃ gas, that is, gas supply time (irradiation time), is set to fall within a range of, for example, 60 to 300 seconds. At this time, the heater unit 207 is set to a temperature such that the temperature of the wafers 200 is set to fall within a range of, for example, 150 to 250 degrees C. The zirconium-containing layer formed on each wafer 200 in Step S105 is oxidized to form a zirconium oxide (ZrO₂, or hereinafter also referred to as ZrO) layer.

### <Step S108>

In Step S108 (see FIGS. 8 and 9, fourth process), the valve 233j of the gas supply pipe 232b is closed and the valve 233g is opened to stop the supply of the O₃ gas into the processing chamber 201 and allow the flow of the O₃ gas into the vent line 232g. At this time, with the APC valve 231a of the exhaust pipe 231 opened, the interior of the processing chamber 201 is vacuum-exhausted by the vacuum pump 231c to exclude an unreacted O₃ gas remaining in the processing chamber 201 or an O₃ gas remaining after contributing to the oxidization.

At this time, the residual gas in the processing chamber 201 may not be completely excluded and the interior of the processing chamber 201 may not be completely purged. If an amount of the residual gas in the processing chamber 201 is very small, this has no adverse effect on the subsequent Step S105. In this case, there is no need to provide a high flow rate of the N₂ gas supplied into the processing chamber 201. For example, approximately the same volume of the N₂ gas as the processing chamber 201 may be supplied into the processing chamber 201 to purge the interior of the processing chamber 201 to such a degree that this has no adverse effect on Step S105. In this way, when the interior of the processing chamber 201 is not completely purged, purge time can be shortened, thereby improving a throughput. This can also limit the consumption of the N₂ gas to the minimum required level for purging.

When a cycle consisting of the above-described Steps S105 to S108 is performed at least one time (Step S109), a zirconium and oxygen-containing insulating film having a predetermined film thickness, that is, a zirconium oxide (ZrO₂, or hereinafter also referred to as ZrO) layer can be formed on each wafer 200. This cycle may be performed once or several times. Thus, a stack of ZrO layers is formed on each wafer 200.

After forming the ZrO layer, the valve 233a of the gas supply pipe 232a is closed, the valve 233b of the gas supply pipe 232b is closed, the valve 233f of the inert gas supply pipe 232f is opened, the valve 233h of the gas supply pipe 232h is opened and the valve 233i of the inert gas supply pipe 232i is opened to flow the N₂ gas into the processing chamber 201. The N₂ gas acts as a purge gas which is capable of purging the interior of the processing chamber 201 and removes a residual gas in the processing chamber 201 from the processing chamber 201 (purge, Step S110). Thereafter, the internal atmosphere of the processing chamber 201 is substituted with the inert gas and the internal pressure of the processing chamber 201 returns to atmospheric pressure (return to atmospheric pressure, Step S111).

Thereafter, the seal cap 219 is lowered by the boat elevator 115 to open the bottom opening of the manifold 209 while carrying the processed wafers 200 from the bottom of the manifold 209 out of the process tube 205 with them supported by the boat 217 (boat unload, Step S112). Thereafter, the processed wafers 200 are discharged out of the boat 217 (wafer discharge, Step S113).

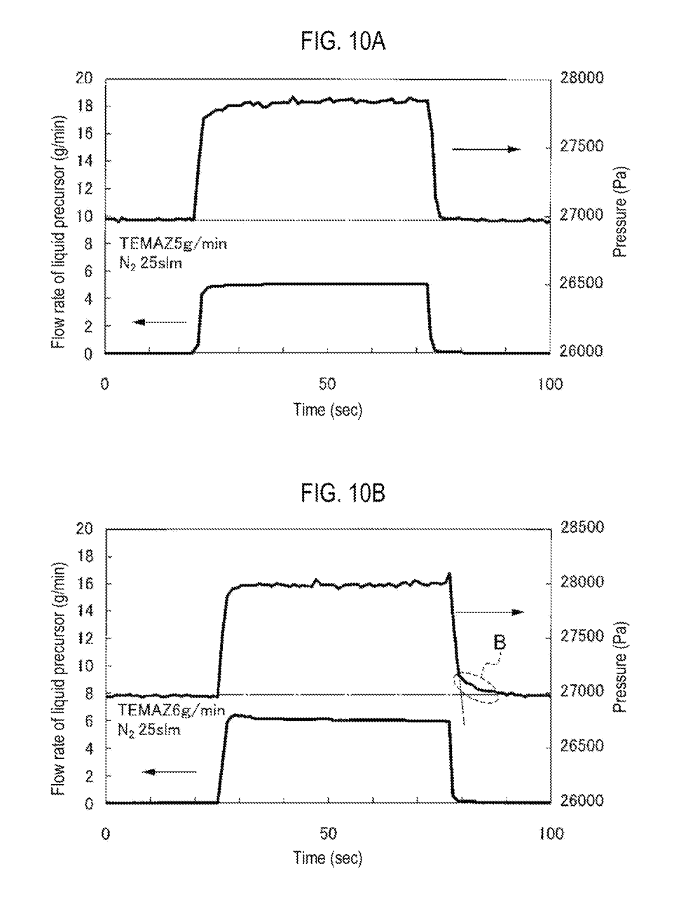

A relationship between a flow rate of the liquid precursor supplied to the vaporizer 270 and a pressure at an outlet of the vaporizer 270 which was measured by the pressure gauge 302 (see FIG. 3) will now be described with reference to FIGS. 10A and 10B. TEMAZ was used as a liquid precursor. A flow rate of the liquid precursor was controlled by the liquid mass flow controller 295c (see FIGS. 3 and 4). FIGS. 10A and 10B show a case where the TEMAZ was vaporized with the flow rate of the TEMAZ set to 5 g/min and a case where the TEMAZ is vaporized with the flow rate of the TEMAZ set to 6 g/min, respectively, under a TEMAZ vaporization condition where a temperature of the vaporizing chamber 274 is 150 degrees C., a dilution N₂ gas supplied from the inert gas supply pipe 232c is 1 slm, a N₂ carrier gas supplied from the inert gas supply pipe 292a into the upper vaporizing chamber 273 is 10 slm, and a N₂ carrier gas supplied from the inert gas supply pipe 292b into the lower vaporizing chamber 275 is 15 slm.

Referring to FIG. 10A, in the case where the TEMAZ was vaporized with the flow rate of the TEMAZ set to 5 g/min, the internal pressure of the gas supply pipe 232a connected to the outlet side of the upper vaporizing chamber 273 has substantially the same rising and falling waveform as the flow rate of the TEMAZ serving as a liquid precursor. Criteria of vaporization state will be described below. If a pressure at a rising flow rate is equal to a pressure at a falling flow rate and a pressure after stopping the supply of the liquid precursor becomes equal to a pressure immediately before the pressure rises, it is determined as good vaporization. In FIG. 10A showing the case where the TEMAZ was vaporized with the flow rate of the TEMAZ set to 5 g/min, it is found to be good vaporization. On the other hand, a state where the pressure at a falling flow rate is higher than the pressure at a rising flow rate, and it takes a prescribed time to return to a pressure before the pressure rises is called “tailing” (see portion B in FIG. 10B). Tailing indicates an effect where a liquid precursor is not sufficiently vaporized and thus the remaining liquid precursor is vaporized with a delay. This state is determined as bad vaporization. In FIG. 10B showing the case where the TEMAZ was vaporized with the flow rate of the TEMAZ set to 6 g/min, it is found to be bad vaporization.

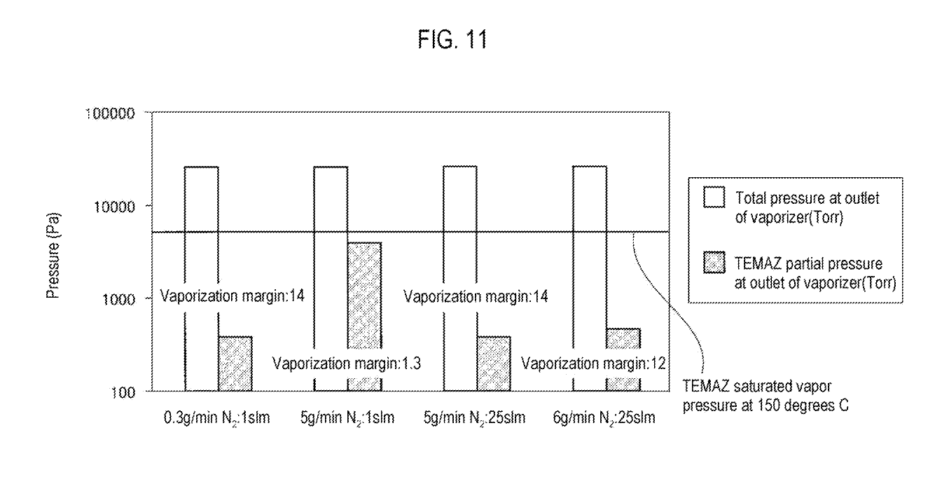

FIG. 11 shows a relationship between a total pressure and a partial pressure at the outlet of the vaporizer 270 depending on vaporization conditions. As used herein, the term “total pressure” refers to a pressure of the entire mixed gas where a plurality of gas species are mixed, and the term “partial pressure” refers to a pressure of each of the plurality of gas species. The total pressure is equal to the sum of the partial pressures of various gases. Since the flow rate of the dilution N₂ gas supplied from the inert gas supply pipe 232c is 26 slm, i.e., equal to the total flow rate of the N₂ carrier gases supplied from the inert gas supply pipe 292a and the inert gas supply pipe 292b, the total pressure at the outlet of the vaporizer 270 is the same for both cases.

Under some vaporization conditions where a flow rate of liquid TEMAZ is 0.3 g/min, a flow rate of the dilution N₂ gas is 25 slm, and a flow rate of the N₂ carrier gas is 1 slm, a vaporization margin is 14 times as large as that at a TEMAZ saturation vapor pressure at 150 degrees C., which is in a range of good vaporization. As used herein, the term “vaporization margin” refers to a ratio of TEMAZ saturation vapor pressure to TEMAZ partial pressure.

Under the vaporization conditions where a flow rate of the liquid TEMAZ is 5 g/min, a flow rate of the N₂ carrier gas is 25 slm, and a flow rate of the dilution N₂ gas is 1 slm, a vaporization margin is 14 times as large as that at the TEMAZ saturation vapor pressure at 150 degrees C., which is in a range of good vaporization. Accordingly, it can be seen that increasing the flow rate of the N₂ carrier gas is effective to reduce the TEMAZ partial pressure at the outlet of the vaporizer 270 and increase the vaporization margin.

On the other hand, with the same flow rates of the dilution N₂ gas and the N₂ carrier gas (the flow rate of dilution N₂ gas is 25 slm and the flow rate of N₂ carrier gas is 1 slm) as those under the aforementioned conditions, if the flow rate of the liquid TEMAZ is increased, the vaporization margin is 1.3 times as large as that at the TEMAZ saturation vapor pressure at 150 degrees C., which is smaller than the vaporization margin 12 times as large as that at the TEMAZ saturation vapor pressure at 150 degrees C. under the conditions where a flow rate of the liquid TEMAZ is 6 g/min, a flow rate of the N₂ carrier gas is 25 slm, and a flow rate of the dilution N₂ gas is 1 slm, which results in poor vaporization.

It can be seen from the above that the increase in the flow rate of the N₂ carrier gas flowing into the vaporizer 270 can provide an increased amount of TEMAZ vaporization while maintaining the vaporization margin.

In some techniques, the maximum flow rate of the N₂ carrier gas supplied from the inert gas supply pipe 292a into the gas inlet space 279 of the upper housing 271 is low (for example, 1 to 2 slm). This is because a joining portion of the liquid precursor and the carrier gas corresponds to the slit-like gap 262 and the flow rate is determined by a slit size of the gap 262. On the other hand, in some embodiments of the present disclosure, in order to lower a partial pressure of a liquid precursor in the vaporizer 270, the slit size of the gap 262 is increased so that the N₂ carrier gas can be abundantly supplied from the inert gas supply pipe 292a into the gas inlet space 279 of the upper housing 271. Accordingly, under the conditions where a flow rate of the liquid TEMAZ is 5 g/min and a total flow rate of the N₂ carrier gases supplied from the inert gas supply pipes 292a and 292b is 25 slm, the vaporization is 14 times as large as that at the TEMAZ saturation vapor pressure at 150 degrees C., which may result in the flow rate of the liquid TEMAZ about 16 times as high under the conditions initially mentioned in this paragraph (0.3 g/min).

As can be seen from FIG. 11, the total pressure at the outlet of the vaporizer 270 is about 26600 Pa, whereas the TEMAZ partial pressure is about 466 Pa, for example when a flow rate of the liquid TEMAZ is 6 g/min and a flow rate of the N₂ carrier gas is 25 slm. Here, the upper limit of a ratio of the partial pressure to a total pressure may be equal to or less than 18% (about 20%), for example. In addition, the lower limit of that ratio may be equal to or greater than the minimum control value of a mass flow controller, for example. If the minimum control value of the mass flow controller is 0.02 g/min, the lower limit of that ratio may be equal to or more than 0.1% of a TEMAZ partial pressure of 24 Pa, for example.

In addition, under the conditions where the temperature of the vaporizing chamber 274 is 150 degrees C., the total flow rate of the N₂ carrier gases is 25 slm, a flow rate of the dilution N₂ gas is 1 slm, a flow rate of the liquid TEMAZ is 0.45 g/min, and TEMAZ supply time is 300 sec, TEMAZ and O₃ were alternately supplied for 75 cycles to form a ZrO₂ film. A step coverage was 81% after forming the film. In contrast, under the conditions where the temperature of the vaporizing chamber 274 is 150 degrees C., the total flow rate of the N₂ carrier gases is 25 slm, a flow rate of the dilution N₂ gas is 1 slm, a flow rate of the liquid TEMAZ is 3 g/min, and TEMAZ supply time is 60 sec, TEMAZ and O₃ were alternately supplied for 75 cycles to form a ZrO₂ film. A step coverage was 81% after forming the film, which resulted in improved step coverage and reduced supply time.

As described above, in some embodiments of the present disclosure, even when a liquid precursor having a low vapor pressure is used, it is possible to increase the amount of vaporization of the liquid precursor and prevent or suppress poor vaporization in the vaporizing chamber. In addition, it is possible to suppress or prevent clogging and foreign matter generated by deposits due to poor vaporization. Further, it is possible to maintain film thickness uniformity. In some embodiments of the present disclosure, a flow rate of the carrier gas flowing into the vaporizing chamber may be set to 5 slm or higher and the internal pressure of the vaporizing chamber may be set to 200 Torr or higher. A flow rate of the liquid precursor may be set to 1 g/min or higher.

Incidentally, the present disclosure can be applied to any kind of film using a precursor having a low vapor pressure. For example, the present disclosure can be appropriately applied to formation of films such as a hafnium oxide film (HfO₂ film), an aluminum oxide film (Al₂O₃ film), a titanium oxide film (TiO film), a zirconium silicon oxide film (ZrSiO film), a hafnium silicon oxide film (HfSiO film), a zirconium aluminum oxide film (ZrAlO film), a hafnium aluminum oxide film (HfAlO film), a titanium nitride film (TiN film), titanium carbon nitride film (TiCN film), a tantalum nitride film (TaN film), a cobalt film (Co film), a nickel film (Ni film), a ruthenium film (Ru film), a ruthenium oxide film (RuO film) and the like.

In addition, the present disclosure can be applied to any gas species other than TEMAZ if they are precursors having a low vapor pressure which are condensed by a certain amount in a pipe before they are supplied into the processing chamber under the above-described conditions. For example, the present disclosure can be appropriately applied to tetrakisethylmethylamino zirconium (Zr[N(CH₃)C₂H₅]₄, abbreviation: TEMAZ), tetrakisdiethylamino zirconium (Zr [N(C₂H₅)₂]₄, abbreviation: TDEAZ), tetrakisdimethylamino zirconium (Zr[N(CH₃)₂]₄, abbreviation: TDMAZ), Zr(MeCp)(NMe₂)₃, tetrakisethylmethylamino hafnium (Hf[N(CH₃)C₂H₅]₄, abbreviation: TEMAH), tetrakisdiethylamino hafnium (Hf[N(C₂H₅)₂]₄, abbreviation: TDEAH), tetrakisdimethylamino hafnium (Hf[N(CH₃)₂]₄, abbreviation: TDMAH), trimethyl aluminum (Al(CH₃)₃, abbreviation: TMA), titanium tetrachloride (TiCl₄), trisdimethylaminosilane (abbreviation: TDMAS), tantalum chloride (TaCl), nickel bis[N,N′-ditertialbutylacetamidinate](Ni(tBu₂-amd)₂, (tBu)NC(CH₃)N(tBu)₂Ni, abbreviation: BDTBANi), Co amd [(tBu)NC(CH₃)N(tBu)₂Co], 2,4-dimethylpentadienyl)(ethylcyclopentadienyl) ruthenium (abbreviation: DER), etc.

In addition, the present disclosure may be implemented by change of process recipes of an existing substrate processing apparatus, for example. The change of process recipes may include installing the process recipes of the present disclosure in the existing substrate processing apparatus via a telecommunication line or a recording medium storing the process recipes and operating input/output devices of the existing substrate processing apparatus to change its process recipes into the process recipes of one or more of the embodiments described.

### ASPECTS OF PRESENT DISCLOSURE

Hereinafter, some aspects of the present disclosure will be additionally stated.

### (Supplementary Note 1)

An aspect of the present disclosure provides a substrate processing apparatus including:

a processing chamber configured to accommodate a substrate;

a vaporized gas supply system which includes a vaporizer to vaporize a liquid precursor into a vaporized gas and is configured to supply the vaporized gas into the processing chamber; and

a control unit configured to control the vaporized gas supply system to supply the liquid precursor and a carrier gas into a vaporization chamber formed in the vaporizer such that a ratio of a partial pressure of the liquid precursor to a total pressure in the vaporization chamber is equal to or lower than 20%.

### (Supplementary Note 2)

The control unit is configured to control the vaporized gas supply system such that the ratio of the partial pressure of the liquid precursor to the total pressure in the vaporization chamber is equal to or higher than 0.1%.

### (Supplementary Note 3)

The substrate processing apparatus further includes a heating system to heat the vaporizer, wherein the control unit is configured to control the heating system and the vaporized gas supply system such that the vaporizer is heated to about 150 degrees C. when the liquid precursor is vaporized.

### (Supplementary Note 4)

The substrate processing apparatus further includes a reaction gas supply system to supply a reaction gas reacting with the vaporized gas into the processing chamber, and

wherein the control unit is configured to control the vaporized gas supply system and the reaction gas supply system such that a film is formed on the substrate accommodated in the processing chamber by supplying the vaporized gas and the reaction gas alternately such that the vaporized gas and the reaction gas are not mixed together.

### (Supplementary Note 5)

The substrate processing apparatus further includes a gas filter interposed between the vaporizer and the processing chamber, and a mist filter interposed between the vaporizer and the gas filter.

### (Supplementary Note 6)

The mist filter is constituted by a combination of a plurality of plates of at least two types having holes at different positions.

### (Supplementary Note 7)

Another aspect of the present disclosure provides a method of manufacturing a semiconductor device, including:

vaporizing a liquid precursor into a vaporized gas by supplying a liquid precursor and a carrier gas into a vaporization chamber of a vaporizer such that a ratio of a partial pressure of the liquid precursor to a total pressure in the vaporization chamber is equal to or lower than 20%; and

supplying the vaporized gas into a processing chamber where a substrate is accommodated, and processing the substrate.

### (Supplementary Note 8)

The liquid precursor is a liquid precursor having such a low vapor pressure that the liquid precursor being condensed by a certain amount before the liquid precursor is supplied into the processing chamber.

### (Supplementary Note 9)

The liquid precursor is one selected from a group consisting of a zirconium-containing precursor, a hafnium-containing precursor, an aluminum-containing precursor, a titanium-containing precursor, a silicon-containing precursor, a tantalum-containing precursor, a cobalt-containing precursor, a nickel-containing precursor and a ruthenium-containing precursor.

### (Supplementary Note 10)

The act of vaporizing the liquid precursor into the vaporized gas includes supplying a liquid precursor of 1 g/min or higher and a carrier gas of 5 slm or higher, with the internal pressure of the vaporization chamber set to 200 Torr or higher.

### (Supplementary Note 11)

The act of vaporizing the liquid precursor into the vaporized gas includes supplying a liquid precursor of 5 g/min or higher into the vaporization chamber.

### (Supplementary Note 12)

The act of vaporizing the liquid precursor into the vaporized gas includes supplying a liquid precursor of 6 g/min or higher into the vaporization chamber.

### (Supplementary Note 13)

The act of vaporizing the liquid precursor into the vaporized gas includes supplying a carrier gas of 25 slm or higher into the vaporization chamber.

### (Supplementary Note 14)

The act of vaporizing the liquid precursor into the vaporized gas includes supplying a carrier gas of 10 slm into the vaporization chamber from the upper side of the vaporizer, supplying a carrier gas of 15 slm into the vaporization chamber from the lower side of the vaporizer, and supplying a carrier gas of at least 25 slm into the vaporization chamber.

### (Supplementary Note 15)

Another aspect of the present disclosure provides a method of processing a substrate, including:

vaporizing a liquid precursor into a vaporized gas by supplying a liquid precursor and a carrier gas into a vaporization chamber of a vaporizer such that a ratio of a partial pressure of the liquid precursor to a total pressure in the vaporization chamber is equal to or lower than 20%; and

supplying the vaporized gas into a processing chamber where a substrate is accommodated, and processing the substrate.

### (Supplementary Note 16)

Another aspect of the present disclosure provides a vaporization system including:

a vaporizer configured to supply a liquid precursor and a carrier gas into a vaporization chamber of a vaporizer such that a ratio of a partial pressure of the liquid precursor to a total pressure in the vaporization chamber is equal to or lower than 20%, and vaporize the liquid precursor into a vaporized gas;

a gas filter; and

a mist filter.

### (Supplementary Note 17)

Another aspect of the present disclosure provides a program that causes a computer to perform a process of vaporizing a liquid precursor, including:

heating a vaporizer; and

supplying a liquid precursor and a carrier gas into a vaporization chamber of the vaporizer such that a ratio of a partial pressure of the liquid precursor to a total pressure in the vaporization chamber is equal to or lower than 20%.

### (Supplementary Note 18)

Another aspect of the present disclosure provides a non-transitory computer-readable recording medium storing a program that causes a computer to perform a process of vaporizing a liquid precursor, including:

heating a vaporizer; and

supplying a liquid precursor and a carrier gas into a vaporization chamber of the vaporizer such that a ratio of a partial pressure of the liquid precursor to a total pressure in the vaporization chamber is equal to or lower than 20%.

### (Supplementary Note 19)

Another aspect of the present disclosure provides a vaporization system used in the substrate processing apparatus of Supplementary Note 1, including:

the vaporizer of the substrate processing apparatus;

a gas filter interposed between the vaporizer and the processing chamber of the substrate processing apparatus; and

a mist filter interposed between the vaporizer and the gas filter.

According to the present disclosure in some embodiments, it is possible to increase a supply amount of a liquid precursor.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a processing chamber configured to accommodate a substrate;
a vaporized gas supply system which includes a vaporizer to vaporize a liquid precursor into a vaporized gas and is configured to supply the vaporized gas into the processing chamber; and
a control unit configured to control the vaporized gas supply system to supply the liquid precursor and a carrier gas into a vaporization chamber formed in the vaporizer such that a ratio of a partial pressure of the liquid precursor to a total pressure in the vaporization chamber is equal to or lower than 20%.

2. The substrate processing apparatus of claim 1, wherein the control unit is configured to control the vaporized gas supply system such that the ratio of the partial pressure of the liquid precursor to the total pressure in the vaporization chamber is equal to or higher than 0.1%.

3. The substrate processing apparatus of claim 1, further comprising a heating system to heat the vaporizer, wherein the control unit is configured to control the heating system and the vaporized gas supply system such that the vaporizer is heated to about 150 degrees C. when the liquid precursor is vaporized.

4. The substrate processing apparatus of claim 1, further comprising a reaction gas supply system to supply a reaction gas reacting with the vaporized gas into the processing chamber, and
wherein the control unit is configured to control the vaporized gas supply system and the reaction gas supply system such that a film is formed on the substrate accommodated in the processing chamber by supplying the vaporized gas and the reaction gas alternately such that the vaporized gas and the reaction gas are not mixed together.

5. The substrate processing apparatus of claim 1, further comprising a gas filter interposed between the vaporizer and the processing chamber, and a mist filter interposed between the vaporizer and the gas filter.

6. The substrate processing apparatus of claim 5, wherein the mist filter includes a combination of a plurality of plates of at least two types having holes at different positions.

7. A vaporization system used in the substrate processing apparatus of claim 1, comprising:
the vaporizer of the substrate processing apparatus;
a gas filter interposed between the vaporizer and the processing chamber of the substrate processing apparatus; and
a mist filter interposed between the vaporizer and the gas filter.
